(19) United States
(12) Patent Application Publication
(10) Pub. No.: US 2002/0100413 A1
(43) Pub. Date: Aug. 1, 2002

(54) Method for growing semiconductor epitaxial layer with different growth rates in selective areas

(76) Inventors: Jeong Soo Kim, Gongju-Si (KR); Ho Sung Cho, Taejon (KR); Kyu-Seok Lee, Taejon (KR)

Correspondence Address: JACOBSON HOLMAN, PLLC., PROFESSIONAL LIMITED LIABILITY COMPANY, 400 Seventh Street, N.W., Washington, DC, 20004, US

(21) Appl. No.: 10/026,530

(22) Filed: Dec. 27, 2001

(30) Foreign Application Priority Data
Jan. 30, 2001 (KR) 2001-4338

(51) Int. Cl. C30B 28/14; C30B 23/00; C30B 25/00; C30B 28/12

(52) U.S. Cl. 117/94

(57) ABSTRACT

Disclosed is a method for depositing a thin dielectric on a portion in which a decreased growth speed of epitaxy is needed in a bridge fashion, and adjusting the width of bridges made of dielectric material and the distance of the bridges deposited, thereby controlling a growth speed and growth thickness of an epitaxial growth layer, which comprising the processes of growing a bridge-shape thin dielectric on a semiconductor substrate for fabricating a semiconductor integrated circuit device, and growing an epitaxial layer with different epitaxial growth rates on selective areas on top of the semiconductor substrate. Thus, the method controls a distance between bridges and a width of the bridge, thereby adjusting a growth speed and growth thickness of an epitaxial layer to be grown in future. Furthermore, the method allows a change in growth characteristics of the epitaxial layer to be smooth, resulting in a decreased light reflection, and allows the change in growth characteristics to be occurred at an extremely small region, thereby efficiently applying to a high-speed revolution epitaxial growth apparatus.

### FIELD OF THE INVENTION

The present invention relates to a method, for use in fabricating a semiconductor integrated circuit device, for growing a semiconductor epitaxial layer with different growth rates in selective areas; and, more particularly, to a method for growing a semiconductor epitaxial layer with different growth rates in selective areas at once epitaxial growth by adjusting a width of bridge-shape thin dielectrics and a distance between nearby bridges.

### DESCRIPTION OF THE PRIOR ART

As a requirement of high-capacity and ultrahigh-speed optical communications increases, recently, a number of developments are under way on various architectures of optical devices. The development of such optical devices is being focused on an integration technique, which enhances characteristics of a simple device and unifies a plurality of devices on a substrate. Such integration technique integrates a multiplicity of optical devices including a semiconductor laser diode serving to convert an electric signal into an optical signal, a light receiving element serving to convert the optical signal into an electric signal, an optical filter, and an optical amplifier in various combinations. Thus, the integration technique allows maximization of the characteristics of the optical device, decrease of a unit cost for device fabrication and creation of a new device with various functions. Accordingly, active studies are under way on the integration technique.

Examples of the optical devices implemented with the integration technique as above include a modulator-integrated DFB-LD, an optical amplifier-integrated optical filter, and a light emitting/receiving element-integrated transceiver. As examples of a technique of integrating the optical devices with different characteristics and structures as mentioned above, there are a butt-coupling, a selective area growth (which is referred to as “SAG” hereinafter), an embedded mask growth (which is referred to as “EMG” hereinafter), and a selective mask growth (which is referred to as “SMG” hereinafter).

In such integration techniques, a required epitaxial growth method is dependent upon a type of optical device to be integrated. For example, in the integration of a semiconductor laser diode and an optical mode size converter of changing a size of light, the reflection of light from a contact surface therebetween has none of an adversely influence. Conversely, in the integration of a semiconductor optical amplifier and the optical mode size converter, the reflection of light from a contact surface has an adversely influence. Accordingly, the SAG technique is applied in integrating the optical amplifier and the optical mode size converter, in lieu of the butt-coupling technique, which may invoke a considerable light reflection.

That is to say, a pertinent integration technique among the techniques is selected responsive to characteristics required by a device to be integrated.

FIGS. 1 to 5 are pictorial representations illustrating a conventional epitaxial growth technique, respectively. A description will be made as to various integration techniques available in the art. FIGS. 1A to 1D are pictorial representations illustrating the conventional epitaxial growth using the butt-coupling technique.

Firstly, as shown in FIG. 1A, an epitaxy 110 having a first structure is grown on a semiconductor substrate 120 made of InP or GaAs. Thereafter, as shown in FIG. 1B, a portion of the epitaxial growth surface is covered with a thin dielectric 130, followed by a partial etch on the epitaxy 110 at a region not covered with the thin dielectric 130 is performed. Next, as shown in FIG. 1C, an epitaxy 140 having a second structure is grown on a portion where the epitaxy 110 is partially etched.

FIG. 1D is a photograph showing an actual optical device obtained by applying the conventional butt-coupling technique to an electro-absorption modulator and a waveguide layer.

The conventional butt-coupling technique allows each of the optical devices to be individually optimized thereby applying it to various types of optical device integrations, and invokes a sharp characteristic change in a contact portion between optical devices thereby featuring a short transition length that represents a characteristic change section as against another integration. If, however, a thickness of a grown epitaxy is excessively thick, the butt-coupling technique suffers from a drawback that it is difficult to control epitaxial growth characteristics at the contact portion between the epitaxy 110 of the first structure and the epitaxy 140 of the second. In addition, it suffers from a drawback that it causes a serious light reflection due to an excessive difference in a refractive index at a coupling portion.

A description will be made as to a conventional epitaxial growth technique using the aforementioned SAG. FIGS. 2A to 2C are pictorial representations illustrating the SAG-based epitaxial growth technique.

Referring to FIG. 2A, the SAG technique covers a portion of a region on which a semiconductor layer is grown with a thin dielectric 220 made of SiNₓ or SiO₂ and loads an wafer onto an epitaxial growth apparatus, thereby growing an epitaxy thereon.

Referring to FIG. 2B, if a semiconductor layer made of, e.g., InP is grown on a substrate 210 obtained by the above process, while an epitaxy fails to grow on the thin dielectric 220, an epitaxy 230 is grown on only an exposed portion in the InP substrate, which is not covered with the thin dielectric 220. The reason is that adatoms which is incident onto the thin dielectric 220 fails to grow due to the thin dielectric 220 so that the adatoms is diffused to adjacent regions that is being grown, wherein the adatoms is a single atom such as In, P, Ga or As, making for the growth, or a polymer thereof. As such, a considerable amount of adatoms is drained to the regions adjacent to the thin dielectric 220 as against a region which is far away therefrom, resulting in a different growth characteristic (e.g., a growth speed) according to a distance spaced from the thin dielectric 220.

FIG. 2B is a fragmentary view taken along the line (1) in FIG. 2A after the epitaxial growth, and FIG. 2C shows a fragmentary view taken along the line (2) in FIG. 2A after the epitaxial growth, which represents the characteristics of the epitaxial growth based on the SAG. That is to say, the SAG technique, during the optical device integration, uses that the characteristics of the epitaxial growth depend on a distance displaced from a thin dielectric. Specifically, the SAG technique takes advantage of a difference in an epitaxy growth speed, or a difference in a growth composition between a semiconductor epitaxy grown at the region adjacent to the thin dielectric and that grown at the region far away therefrom.

As a device having the ability to efficiently use the SAG technique, there is a semiconductor laser diode in which an optical mode size converter is integrated. In case an energy band gap of a portion to be used as the optical mode size converter is smaller than that of laser emitted from the semiconductor laser diode as a characteristic of semiconductor, since the light emitted from the semiconductor laser diode is absorbed into the portion of the optical mode size converter, the energy band gap of the portion to be used as the optical mode size converter should be larger than that of the semiconductor laser diode. If a thin dielectric is deposited near a portion on which the semiconductor laser diode is fabricated for an epitaxy growth, while a growth speed of the epitaxy at a region near to the thin dielectric increases, that of the epitaxy at a region far away therefrom, i.e., a region on which the optical mode size converter is fabricated, decreases. Specifically, while a growth thickness of the region on which the semiconductor laser diode is fabricated increases, that of the region on which the optical mode size converter is fabricated decreases.

Therefore, in case a quantum well structure is applied to the SAG, since an energy band gap of the quantum well with a thin growth thickness undergoes a blue shift as against a quantum well with a thick growth thickness, the energy band gap of the region near to the thin dielectric is smaller than that of the region far away therefrom, thereby failing for the optical mode size converter to absorb the light emitted from the semiconductor laser diode.

A transition length, which is maximized a growth speed difference in the SAG with the characteristics as stated above, is known as approximately 150 μm, and this value does not drastically change according to a change in a growth condition. The reason is that the conventional SAG technique is based on a diffusion originated with a concentration gradient of the adatoms in a gas phase. Thus, the conventional SAG suffers from a drawback that it fails to obtain a sharp composition change or a sharp growth thickness change within a distance of several micrometers so that it is difficult to apply to a structure subject to a sharp growth characteristic change. In spite of the drawbacks, since there is no a light reflection in the transition length, the SAG technique is useful in integrating devices which is sensitive to a light reflection in semiconductor junction interface.

A description will be made as to a conventional epitaxial growth technique using the EMG. FIGS. 3A to 3C are pictorial representations illustrating the EMG-based epitaxial growth technique.

The EMG technique allows a thickness of an epitaxial growth layer grown at an EMG region to be smaller than that of a planar substrate, thereby causing a blue shift of energy band gap in a quantum well structure relative to one other than the EMG region. Specifically, the EMG uses that, in case a trench is formed on a substrate to grow an epitaxy, a growth speed of the epitaxy grown at the inside of the trench is slow than that of an epitaxy grown at a region having none of the trench.

Referring to FIG. 3A, fabricated is an overhang structure wherein a spacer 330 followed by a thin dielectric 320 is formed on top of a substrate 310. In this case, a semiconductor layer, which may be selectively etched with respect to a dielectric or a spacer, is used as a material of the thin dielectric 320.

FIG. 3B is a fragmentary view taken along the line (1) in an epitaxial growth structure obtained after an epitaxy 340 is grown on the substrate 310 fabricated as FIG. 3A, and FIG. 3C shows a fragmentary view taken along the line (2) in FIG. 3A similarly. In FIGS. 3B and 3C, the thin film 320 is used as a dielectric. Referring to FIGS. 3B and 3C, in the EMG-based epitaxial growth technique, if a depth of a trench (i.e., a thickness of the spacer plus that of the thin dielectric) increases, a diffused distance of the adatoms is decreased so that an amount of adatoms to be provided to bottom of the trench is decreased, resulting in a decreased growth speed. In addition, since a width of the bottom of the trench in a region on which the epitaxy is grown is wider than that of an opening of the thin dielectric 320, a concentration of the adatoms to be incident on the bottom of the trench is decreased so that a growth speed of the epitaxy at the trench is slow than that at a plane other than the trench. Therefore, if it is applied to the quantum well structure, a growth thickness at the inside of the trench becomes thin, resulting in the blue shift of wavelength relative to the plane region.

Unfortunately, the EMG-based epitaxial growth technique suffers from drawbacks that it further requires a process of growing the spacer 330 for forming the trench on the substrate, a decrease rate in the growth speed is sensitive to a width and thickness of the trench, and a spacer with a significant thickness is required for a trench with a wide width.

FIG. 4 is a graphical representation illustrating a variation of an epitaxial growth speed with a depth or width of a trench during the EMG-based epitaxial growth. Referring to FIG. 4, when a depth of the trench is 5 μm, a width of the trench should be adjusted within 5 μm to obtain a significant degree of growth speed difference. When a thickness and width of the trench is 5 μm and over 20 μm, respectively, a decrease in growth speed is not presented. Through the result of the above process, a width of epitaxy with a uniform property should be above 5 μm at minimum to easily fabricate a useful optical device. Accordingly, in view of the result obtained by R. Westphalen et al., a thickness of the trench should be above 10 μm to obtain a difference in a sufficient growth speed. Unfortunately, the EMG-based epitaxial growth technique suffers from a drawback that a spacer with an increased thickness is required to fabricate the trench with the aforementioned thickness, resulting in a degraded economical efficiency.

Finally, a description will be made as to the conventional epitaxial growth technique using the selective mask growth (SMG) with reference to FIG. 5.

As shown in FIG. 5, unlike the EMG-based epitaxial growth technique stated above, the SMG-based epitaxial growth technique allows a mechanical shadow mask 510 to function as a trench without forming the trench on the growth surface. Since the adatoms contributable to growth is provided by only lateral diffusion, a growth speed at a portion covered with the mechanical shadow mask 510 is slow than that at a portion uncovered with the mechanical shadow mask 510. Although the SMG-based technique with the aforementioned features is cost effective in that no any process is performed to a wafer surface, unlike the SAG-based or the EMG-based techniques, it suffers from a drawback that since a transition length of the growth thickness is significantly long, it fails to apply to a device which a shorten transition length is needed. To boot, the SMG-based technique places the mechanical shadow mask 510 on the substrate so that it fails to efficiently apply to a high-speed revolution epitaxial growth apparatus.

### SUMMARY OF THE INVENTION

It is, therefore, a primary object of the present invention to provide a method, which is capable of depositing a thin dielectric on a portion in which a decreased growth speed of epitaxy is needed in a bridge fashion, and adjusting a width of thin dielectric bridges and a distance between of bridges, thereby controlling a growth speed and growth thickness of an epitaxial growth layer.

In accordance with an aspect of the present invention, there is provided a method for growing a semiconductor epitaxial layer with different growth rates on selective areas, which comprising the steps of: growing a bridge-shape thin dielectric on a semiconductor substrate for fabricating a semiconductor integrated circuit device; and growing an epitaxial layer with different epitaxial growth rates on selective areas on top of the semiconductor substrate.

Preferably, the step of growing the bridge-shape thin dielectric includes the steps of sequentially forming a first selective etch layer, a spacer, a second selective etch layer and the thin dielectric on the semiconductor substrate; processing the thin dielectric to create a rectangular shape of two thin dielectrics spaced at a certain distance from each other, and forming the bridge-shape thin dielectric between the two thin dielectrics; and applying a selective wet etch to the two thin dielectrics having the rectangular shape, thereby forming the spacer into two spacers having a rectangular shape.

### BRIEF DESCRIPTION OF THE DRAWING

The above and other objects and features of the present invention will become apparent from the following description of the preferred embodiments given in conjunction with the accompanying drawings, in which:

FIGS. 1A to 1D are pictorial representations illustrating the conventional epitaxial growth using the butt-coupling technique, respectively;

FIGS. 2A to 2C are pictorial representations illustrating the SAG-based epitaxial growth technique, respectively;

FIGS. 3A to 3C are pictorial representations illustrating the EMG-based epitaxial growth technique, respectively;

FIG. 4 is a graphical representation illustrating a variation of an epitaxial growth speed with a depth or width of a trench during the EMG-based epitaxial growth;

FIG. 5 is a pictorial representation illustrating the conventional epitaxial growth technique using the selective mask growth (SMG);

FIG. 6 is a pictorial representation illustrating a method of growing semiconductor epitaxial layer using BMG technique in accordance with a preferred embodiment of the present invention;

FIGS. 7A to 7D are pictorial representations illustrating a procedure of growing an epitaxial layer using a bridge-shape thin dielectric in accordance with a preferred embodiment of the present invention, respectively;

FIG. 8A is a pictorial representation showing prior to the growth of the epitaxial layer to be formed by the present invention;

FIG. 8B is a pictorial representation showing after the growth of the epitaxial layer;

FIG. 9A is a cross sectional view of the epitaxial layer formed by the bridge-shape thin dielectric in accordance with the present invention;

FIG. 9B is a top plan view of the semiconductor substrate having the bridge-shape thin dielectric for obtaining the structure shown in FIG. 9A;

FIG. 10 is a graphical representation illustrating the result obtained by measuring the change in FIG. 9A through the use of a surface profiler; and

FIG. 11 is a graphical representation illustrating a change in the thickness of the epitaxial layer varying according to a bridge width in the thin dielectric and a bridge distance, which is obtained through the actual experiments.

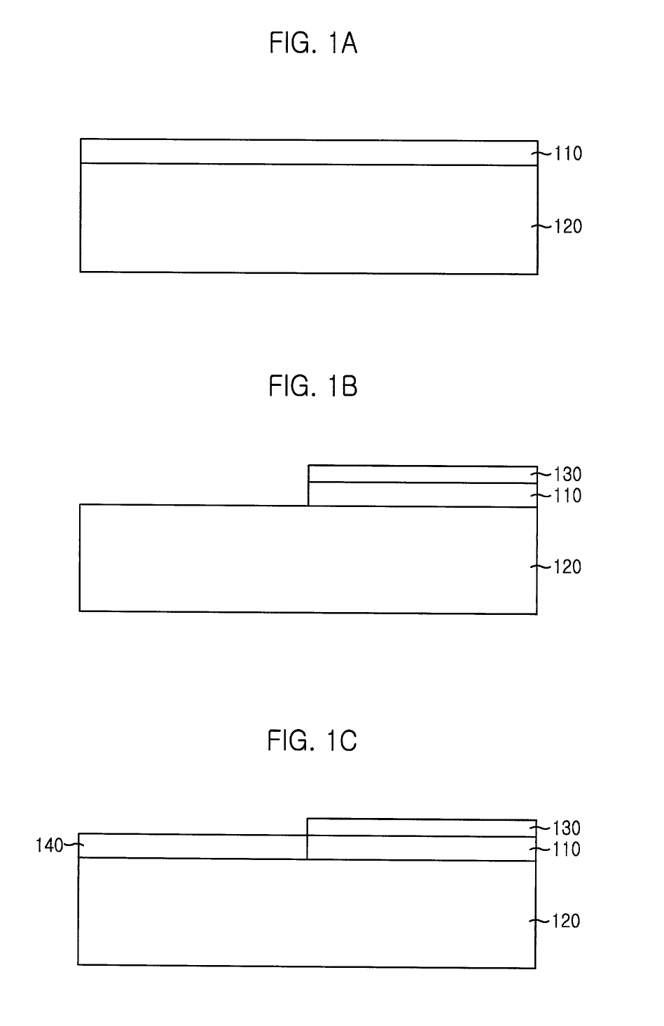

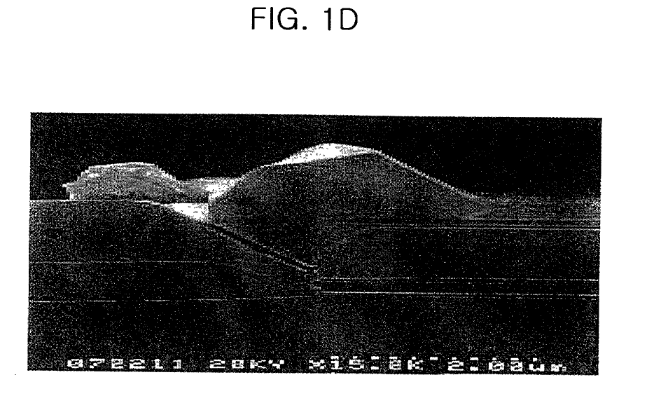

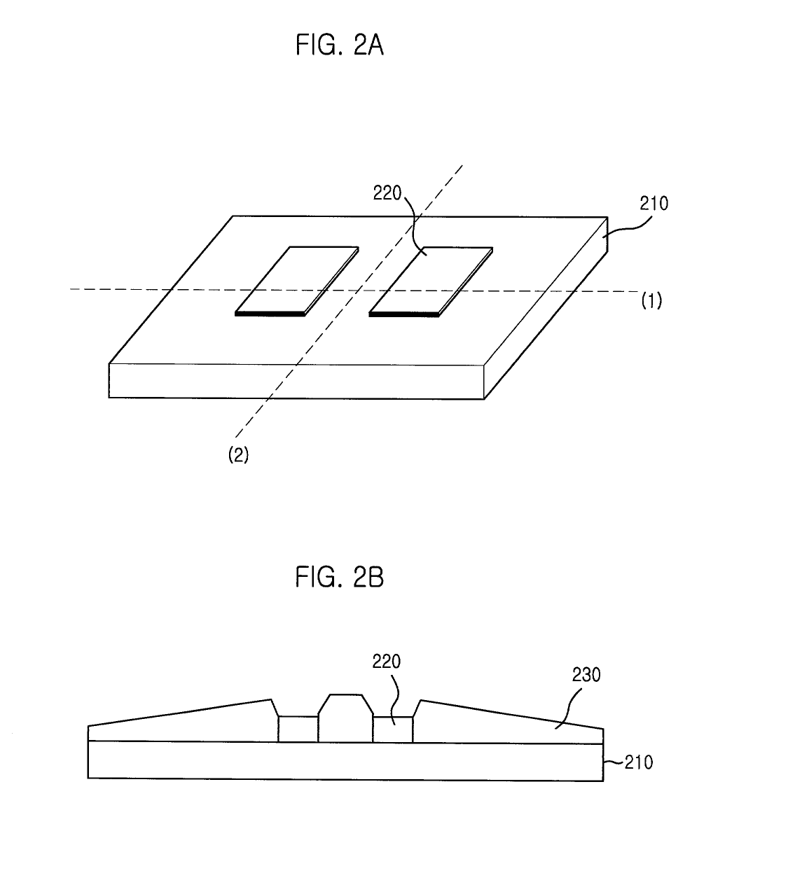

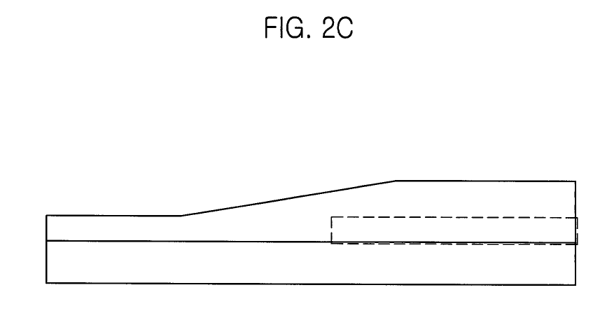

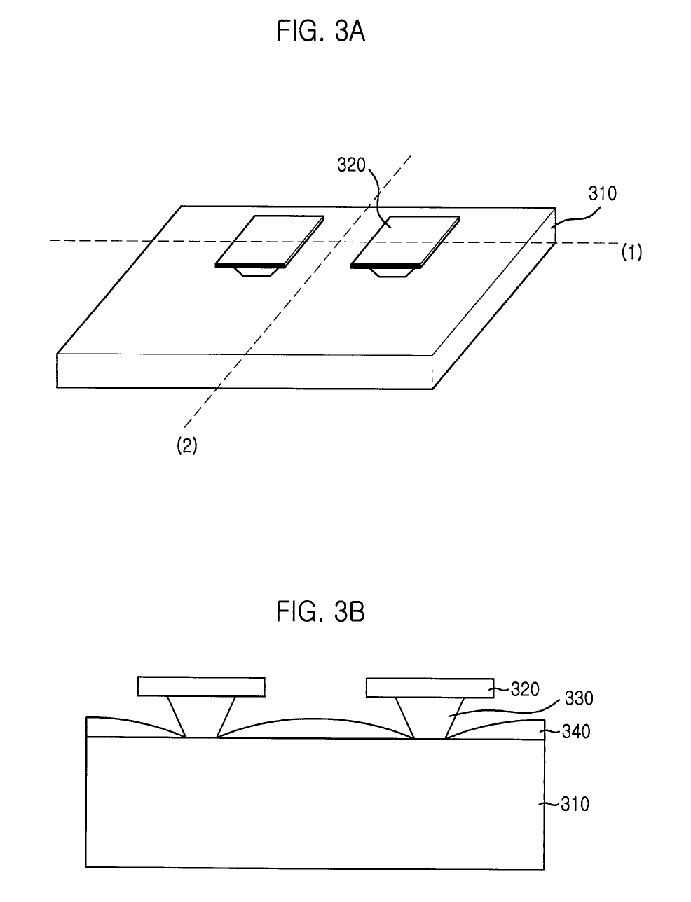

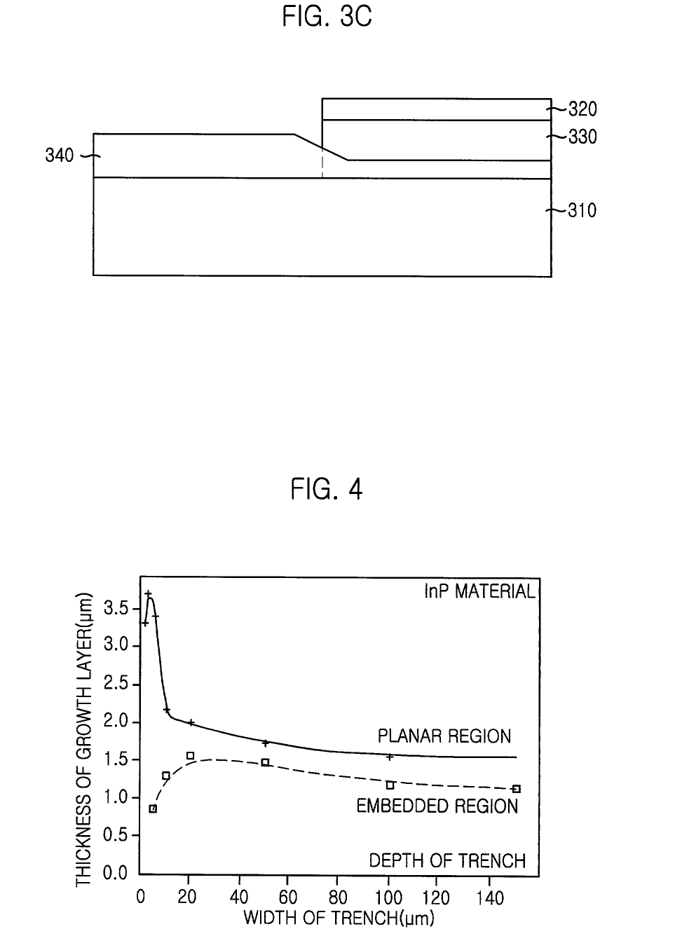

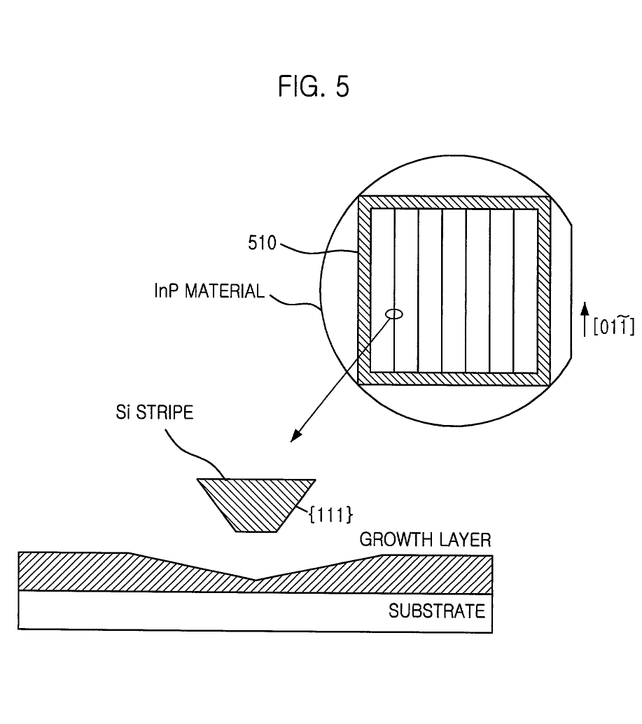

### DETAILED DESCRIPTION OF THE PREFERRED EMBODIMENTS

In this specification, “Bridge Masked Growth (BMG)” technique means a technique that controls a growth speed and growth thickness of an epitaxial growth layer, by adjusting the width of bridges and the distance between the bridges deposited in the deposition of a thin dielectric on a portion in which a decreased growth speed of epitaxy is needed in a bridge fashion.

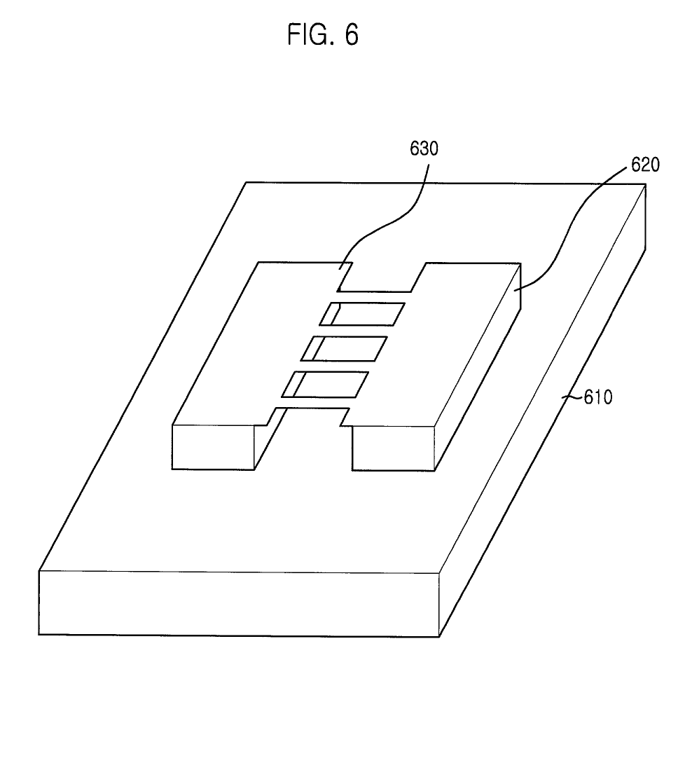

FIG. 6 is a pictorial representation illustrating a method of growing semiconductor epitaxial layer using BMG technique in accordance with a preferred embodiment of the present invention.

Referring to FIG. 6, a spacer 620 followed by a thin dielectric 630 made of SiNₓ or SiO₂ is deposited on a semiconductor substrate 610, wherein the thin dielectric 630 is formed in a bridge fashion.

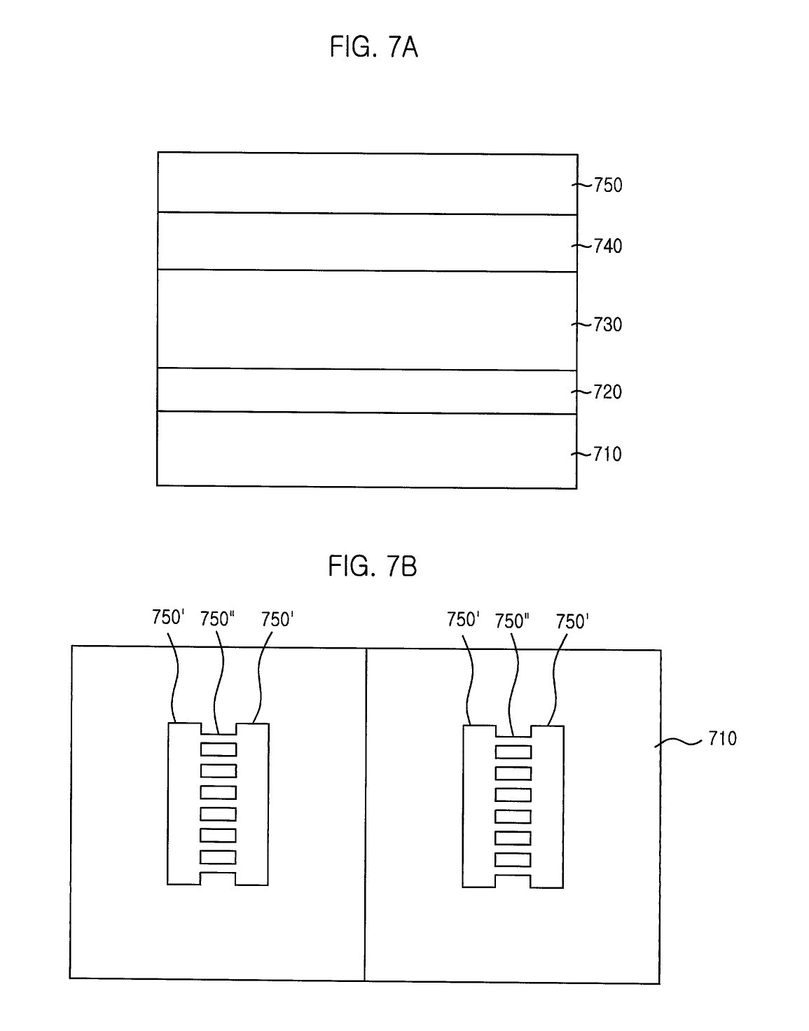

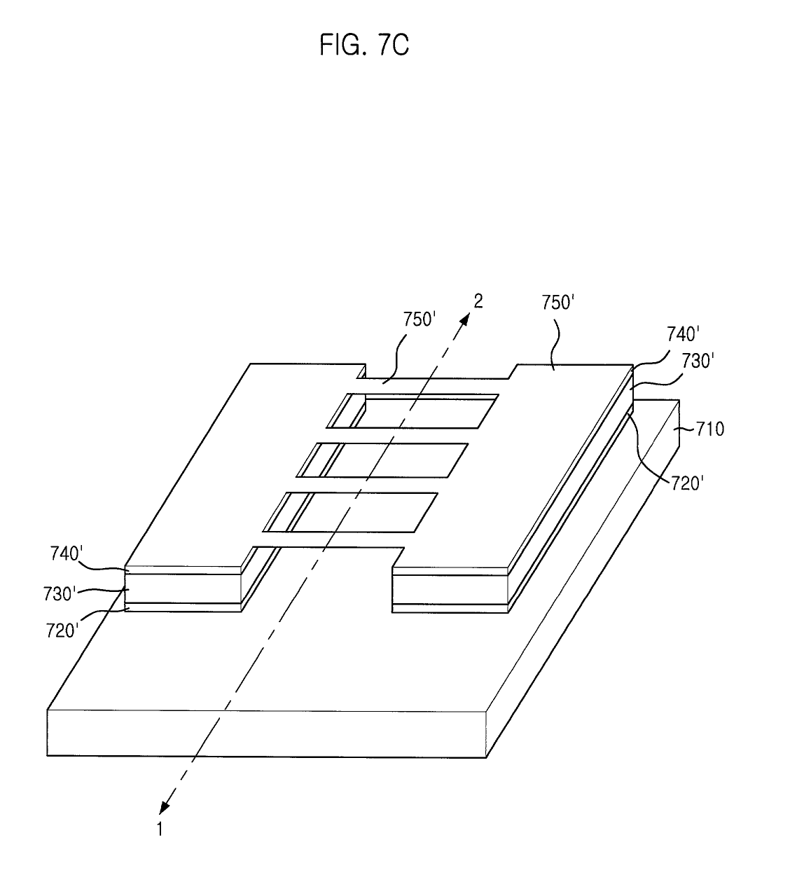

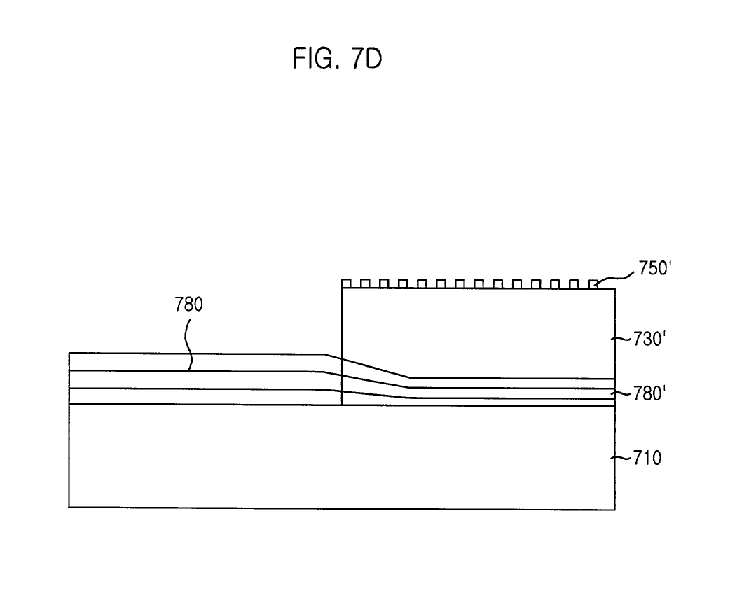

FIGS. 7A to 7D are pictorial representations illustrating a procedure of growing an epitaxial layer using a bridge-shape thin dielectric in accordance with a preferred embodiment of the present invention, respectively.

Referring to FIG. 7A, a selective etching layer 720 made of InGaAs is formed on top of a semiconductor substrate 710 made of InP. Next, a spacer 730 followed by a selective etching layer 740 made of InGaAs is deposited on the selective etching layer 720. Thereafter, a thin dielectric 750 made of SiNₓ or SiO₂ is deposited on top of the selective etching layer 740 using a chemical vapor deposition (CVD).

In this case, the selective etching layer 720 is used to obtain a flat bottom after the application of a selective wet process at the etch of the spacer 730.

In an ensuing step, as shown in FIGS. 7B and 7C, a photolithographic process is applied to the thin dielectric 750 to create two thin dielectrics 750′ of a rectangular shape. FIG. 7B is a fragmentary plan view of the thin dielectric formed in a bridge fashion. The two thin dielectrics 750′ are spaced at a certain distance from each other. Subsequently, the two thin dielectrics 750′ are etched with a bridge-shape thin dielectric 750″ remained, which serves to connect between the two thin dielectrics 750′. After that, the spacer 730 and the selective etching layer 740 is selectively wet etched using the two thin dielectrics 750′ as a mask, so that two spacers 730′ of a rectangular shape, which are spaced at a certain distance from each other, are formed.

In this case, the selective wet etch is used to allow the spacer under the bridge-shape thin dielectric 750″ by a lateral directional diffusion of etchant to be completely etch, and only the spacer under the thin dielectrics 750′ to be remained during the etch. Such etch may be accomplished by designing such that a width of the bridge-shape thin dielectric 750″ be extremely smaller than that of the thin dielectrics 750′.

A description will be made as to the function of the bridge-shape thin dielectric 750″ formed by the BNG-based growth technique of the present invention. As the SAG-based growth technique mentioned above, the bridge-shape thin dielectric 750″ prevents an epitaxial growth from being grown on its surface. Specifically, the bridge-shape thin dielectric 750″ serves to prevent an adatoms necessary for the epitaxial growth from being diffused. That is to say, when there is no an open region between bridges, i.e., a distance between the bridges, the adatoms fails to diffuse on the surface of the semiconductor substrate thereby disabling the epitaxial from being grown; and when the width of the bridges is decreased or the open region is increased, a diffusion blocking force is decreased to activate the epitaxial growth. In addition, when the whole regions are completely opened, the diffusion of the adatoms by the bridges fails to decrease, resulting in an active epitaxial growth. Accordingly, a growth speed of the epitaxy and a thickness of the epitaxial layer depend on the width of each bridge made of the thin dielectric and the distance between the bridges.

Subsequently, a structure shown in FIG. 7D is obtained by loading the semiconductor substrate having the structure shown in FIG. 7C to a Metal Organic Chemical Vapor Deposition (MOCVD) apparatus. FIG. 7D is a fragmentary view taken along the line 1-2 in FIG. 7C after the epitaxial growth. In FIG. 7D, the epitaxy is gradually varied.

Specifically, as shown in FIG. 7D, while an epitaxy 780′ grown at a portion where the thin dielectric is formed in the bridge form 750′ has a slow growth speed thereby resulting in a thin epitaxy layer, an epitaxy 780 grown at a portion having none of the thin dielectric has a fast growth speed thereby resulting in a thick epitaxy layer. As such, just once epitaxial growth causes the different epitaxial growth rates on selective areas, thereby making it possible to form a structure having a smooth change in an epitaxial growth characteristic.

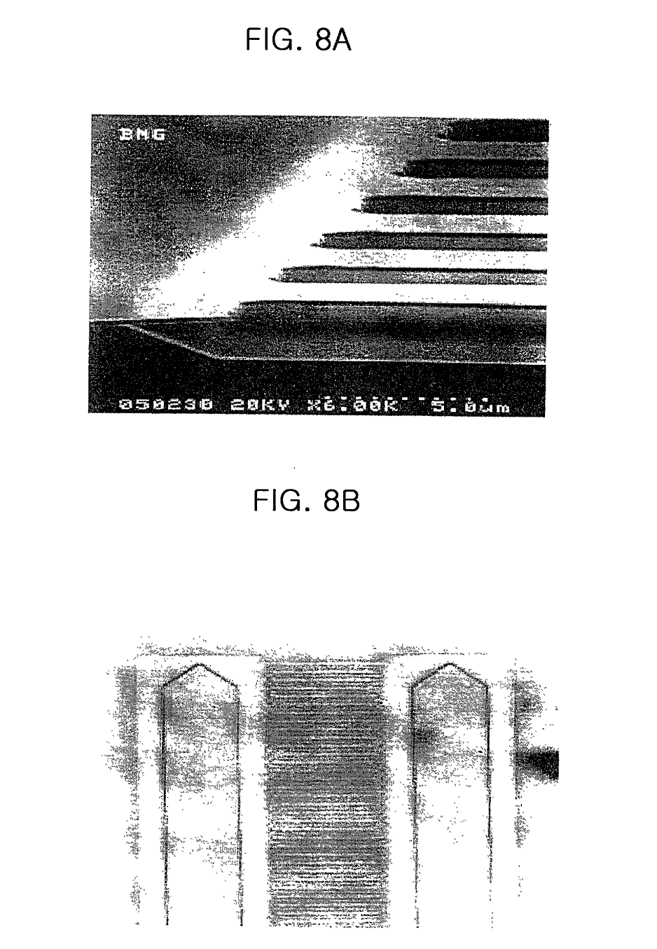

FIG. 8A is a pictorial representation showing prior to the growth of the epitaxial layer to be formed by the present invention and FIG. 8B is a pictorial representation showing after the growth of the epitaxial layer.

Referring to FIGS. BA and 8B, it can be appreciated that the bridge-shape thin dielectric is good formed and good remained even after the epitaxial layer is formed.

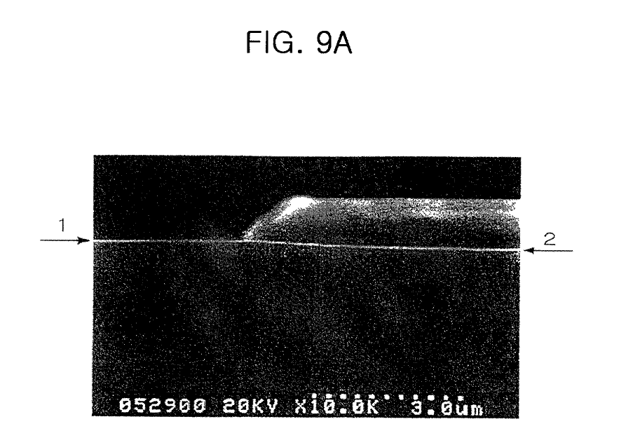

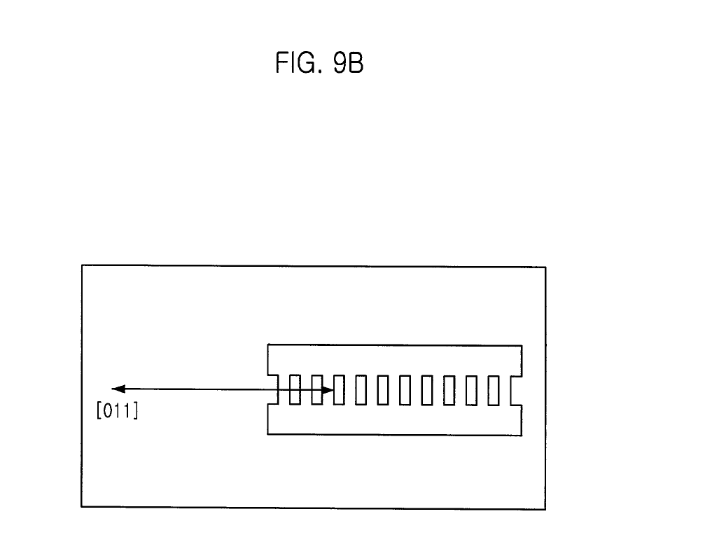

FIG. 9A is a cross sectional view of the epitaxial layer formed by the bridge-shape thin dielectric in accordance with the present invention.

Referring to FIG. 9A, it can be appreciated that a proportionally low height would be given to the epitaxial layer in response to the direction from 1 to 2. Specifically, an epitaxial growth speed at a portion having the bridge-shape thin dielectric is slow as against that at a portion having none of the bridge-shape thin dielectric.

FIG. 9B is a top plan view of the semiconductor substrate having the bridge-shape thin dielectric for obtaining the structure shown in FIG. 9A. In other words, FIG. 9A is a fragmentary view taken along the arrow section (011 direction) in FIG. 9B.

It can be appreciated that the change in the growth speed in FIG. 9A is concentrated within 3.0 μm from a boundary between a plane and a bridge pattern.

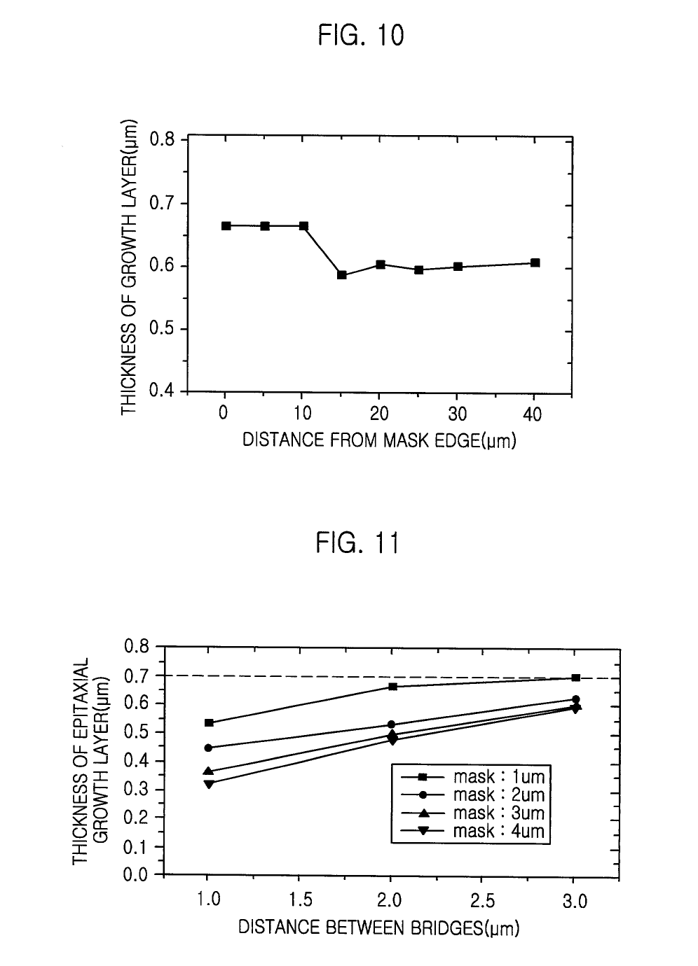

FIG. 10 is a graphical representation illustrating the result obtained by measuring the change in FIG. 9A through the use of a surface profiler.

Referring to FIG. 10, a point showing a sharp change in the growth thickness represents the boundary between the portion having the bridge-shape thin dielectric and that having none of the bridge-shape thin dielectric. As is apparent from FIGS. 9A and 10, the growth thickness changes are equal with one another.

A description will be made as to the relationship between a growth speed and a growth thickness of the epitaxial layer based on the BMG technique of the present invention.

FIG. 11 is a graphical representation illustrating a change in the thickness of the epitaxial layer varying according to a bridge width in the thin dielectric and a bridge distance, which is obtained through the actual experiments.

Referring to FIG. 11, a thickness of the epitaxial layer to be grown becomes thicker as the open region between the bridges becomes larger. In addition, referring to FIG. 10, it can be appreciated that for the same open region, the thickness of the epitaxial layer is decreased with an increase in the width of the bridge as indicated by a mask in FIG. 11. Thus, the growth speed and the growth thickness of the epitaxial layer may be adjusted by controlling the bridge width and the bridge distance.

As demonstrated above, the present invention forms a thin dielectric on a semiconductor substrate in a bridge fashion, controls a distance between bridges and a width of the bridge, thereby adjusting a growth speed and growth thickness of an epitaxial layer to be grown in future. Furthermore, the present invention allows a change in growth characteristics of the epitaxial layer to be smooth, resulting in a decreased light reflection. Moreover, the present invention allows the change in growth characteristics to be occurred at an extremely small region, thereby efficiently applying to a high-speed revolution epitaxial growth apparatus.

Although the preferred embodiments of the invention have been disclosed for illustrative purposes, those skilled in the art will appreciate that various modifications, additions and substitutions are possible, without departing from the scope and spirit of the invention as disclosed in the accompanying claims.

What is claimed is:

1. A method for growing a semiconductor epitaxial layer with different epitaxial growth rates on selective areas, which comprising the steps of:
(a) growing a bridge-shape thin dielectric on a semiconductor substrate for fabricating a semiconductor integrated circuit device; and
(b) growing an epitaxial layer with different epitaxial growth rates on selective areas on top of the semiconductor substrate.

2. The method as recited in claim 1, wherein the step (a) includes the steps of:
(a1) sequentially forming a first selective etch layer, a spacer, a second selective etch layer and the thin dielectric on the semiconductor substrate;
(a2) processing the thin dielectric to create a rectangular shape of two thin dielectrics spaced at a certain distance from each other, and forming the bridge-shape thin dielectric between the two thin dielectrics; and
(a3) applying a selective wet etch to the two thin dielectrics having the rectangular shape, thereby forming the spacer into two spacers having a rectangular shape.

3. The method as recited in claim 1, wherein the step (b) uses a Metal Organic Chemical Vapor Deposition (MOCVD).

4. The method as recited in claim 1, wherein the step (b) controls a growth speed and growth thickness of the epitaxial layer by adjusting a width and distance between the bridge-shape thin dielectrics.

5. The method as recited in claim 1, wherein the thin dielectric is made of SiO₂ or SiNₓ.

6. The method as recited in claim 2, wherein the thin dielectric at the step (a1) is formed by a chemical vapor deposition (CVD).

7. The method as recited in claim 2, wherein the step (a2) is performed by a photolithography.
